(19) United States
(12) Patent Application Publication
(10) Pub. No.: US 2014/0151099 A1
(43) Pub. Date: Jun. 5, 2014

(54) WIRING BOARD AND LASER DRILLING METHOD THEREOF

(71) Applicant: UNIMICRON TECHNOLOGY CORP., TAOYUAN HSIEN (TW)

(72) Inventors: CHENG MING WENG, NEW TAIPEI CITY (TW); WEI-MING CHENG, KAOHSIUNG CITY (TW); HAN-PEI HUANG, TAOYUAN COUNTY (TW)

(73) Assignee: UNIMICRON TECHNOLOGY CORP., TAOYUAN HSIEN (TW)

(21) Appl. No.: 13/845,339

(22) Filed: Mar. 18, 2013

(30) Foreign Application Priority Data
Dec. 3, 2012 (TW) 101145296

(51) Int. Cl. H05K 1/11; H05K 3/46

(52) U.S. Cl. CPC H05K 1/115; H05K 3/4644
USPC 174/258; 174/262; 264/400

(57) ABSTRACT

A laser drilling method of a wiring board is provided. In the method, a laser beam shines on a wiring substrate including an insulating layer to remove a portion of the insulating layer. The wiring substrate is placed in a focus section of the laser beam. The focus section contains a central region, an optical axis located in the central region, and a peripheral region surrounding the central region. The maximum light intensity of the focus section is located in the peripheral region.

### BACKGROUND

1. Technical Field

The present disclosure relates to a wiring board and a drilling method thereof, in particular, to a wiring board having blind via structure and the method of drilling the wiring board using a laser beam.

2. Description of Related Art

Currently, manufacturing method of wiring board has already uses a focused laser beam to manufacture blind via on the wiring board. For the power intensity of the focused laser beam to increase to the maximum to accelerate the formation of blind via, the light intensity distribution of the focused laser beam in general is a Gauss distribution. That is the laser mode of the focused laser beam is the Gauss mode or a TEM₀₀ mode.

When utilizes the focused laser beam having the Gauss distribution to form a blind via, the opening diameter of the blind via formed is larger than the bottom diameter of the blind via. In general, the blind via formed has low via diameter ratio, wherein the diameter ratio is the ratio between the bottom diameter of the blind via and the opening diameter thereof. Such that as the via diameter ratio becomes smaller, the opening diameter of blind via becomes larger than the bottom diameter thereof.

However, the blind via with relative low via diameter ratio in general may have bad influence to the wiring board structure and reduce the associated reliability. Currently, the focused laser beam with light intensity distribution of a top-hat distribution have been used to form the blind via as shown in FIG. 1 to increase the via diameter ratio of the blind via on the wiring board.

FIG. 1 show a diagram illustrating a typical focused laser beam with light intensity distribution of a top-hat distribution. The horizontal axis of FIG. 1 represents the distance of the focused laser beam from the optical axis, and the zero points of the horizontal axis correspond to the position of the optical axis. Please refer to FIG. 1, the focused laser beam described herein can be generated using a beam shaper. The light intensity distribution 10 of the focused laser beam is basically uniform. In other words, the light intensity of the focused laser beam in the central region is substantially equal to the light intensity thereof in the edge region 12.

Since the focused laser beam with the top-hat distribution has uniform light intensity distribution 10, thus when this focused laser beam shines on the wiring substrate forming a facula on the surface of the wiring substrate, the power of the focused laser beam is substantially uniformly distributed within the facula. Hence, the focused laser beam with the top-hat distribution can increase the via diameter ratio of the blind via in comparison to the focused laser beam with the Gauss distribution. However, generally speaking, the focused laser beam still has limitation regardless having the Gauss distribution or the top-hat distribution and is difficult to improve on the via diameter ratio. For instance, it is difficult for the existing focused laser beam to increase the via diameter ratio to 075.

### SUMMARY

The present disclosure provides a laser drilling method of a wiring board which can increase the aspect ratio of blind via.

The present disclosure further provides a wiring board which can be manufactured using the aforementioned laser drilling method.

An exemplary embodiment of the present disclosure provides a laser drilling method of a wiring board. The method comprises shining a laser beam on a wiring substrate including an insulating layer to remove a portion of the insulation layer. The wiring substrate is placed in a focus section of the laser beam. The focus section has a central region, an optical axis located in the central region, and a peripheral region surrounding the central region. A maximum light intensity of the focus section appeared in the peripheral region.

An exemplary embodiment of the present disclosure provides a wiring board which includes an insulation layer, two wiring layers, and at least a conductor. The insulation layer disposed between the wiring layers. The conductor is disposed in the insulation layer and is electrically connected to the wiring layer. The conductor has a first end and a second end opposite to the first end. The width of the first end is larger than the width of the second end. The ratio of the width of the second end to the width of the first end is larger than or equal to 0.75.

To sum up, the present disclosure can increase the via diameter ratio by using a laser beam with the maximum light intensity appeared in the peripheral region such that the reliability can be increase

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a diagram illustrating a typical focused laser beam with light intensity distribution of a top-hat distribution.

FIG. 2A˜FIG. 2G respectively show the flowchart diagram illustrating a laser drilling method for manufacturing a wiring board provided in accordance to an exemplary embodiment of the present disclosure.

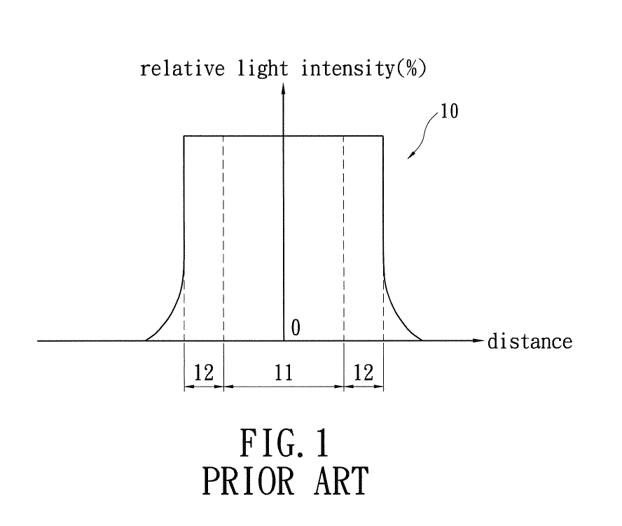

### DESCRIPTION OF THE EXEMPLARY EMBODIMENTS

Reference will now he made in detail to the exemplary embodiments of the present disclosure, examples of which are illustrated in the accompanying drawings. Wherever possible, the same reference numbers are used in the drawings and the description to refer to the same or like parts.

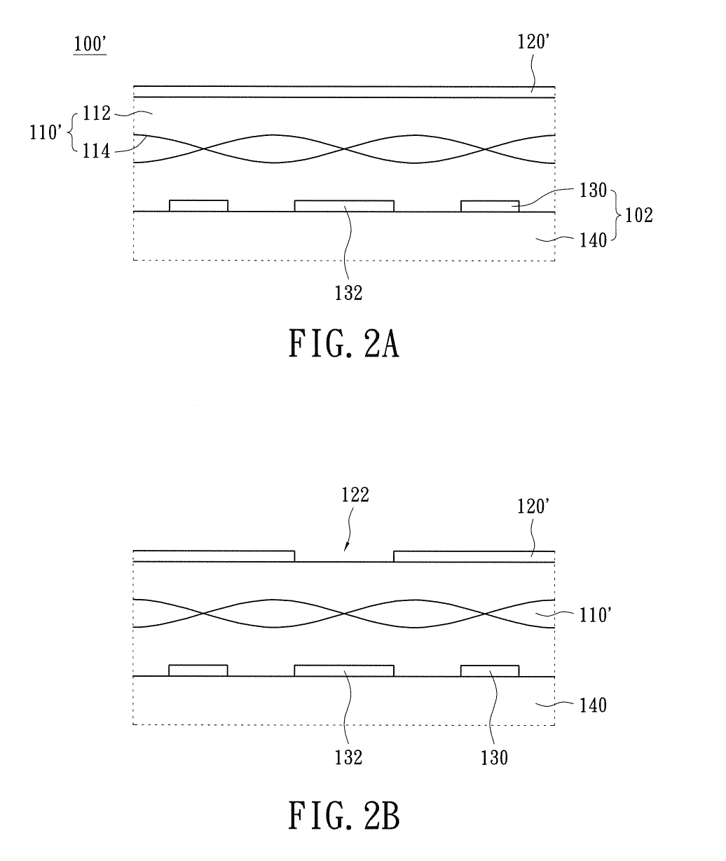

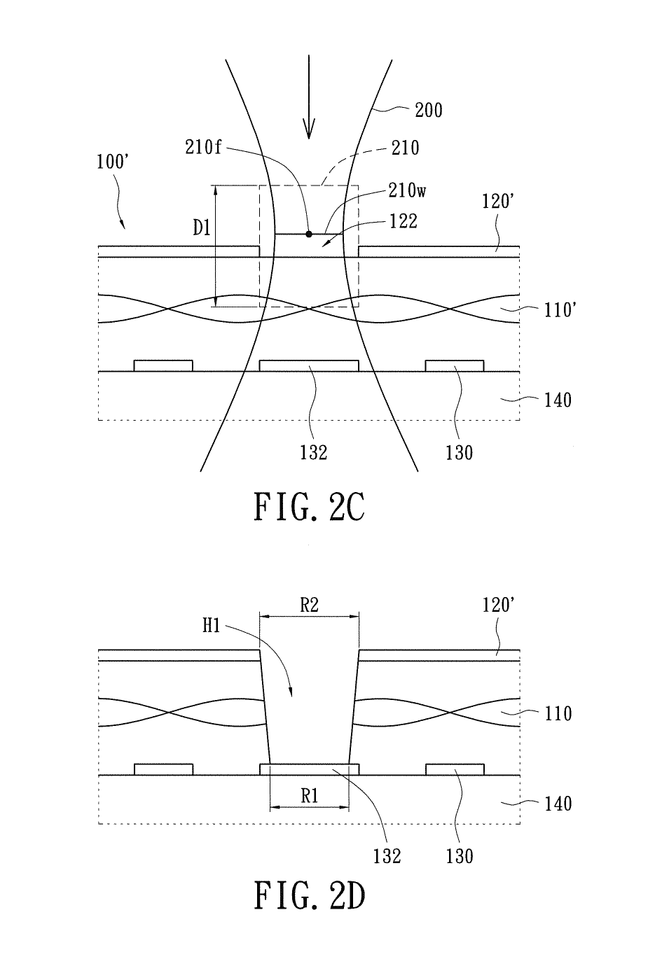

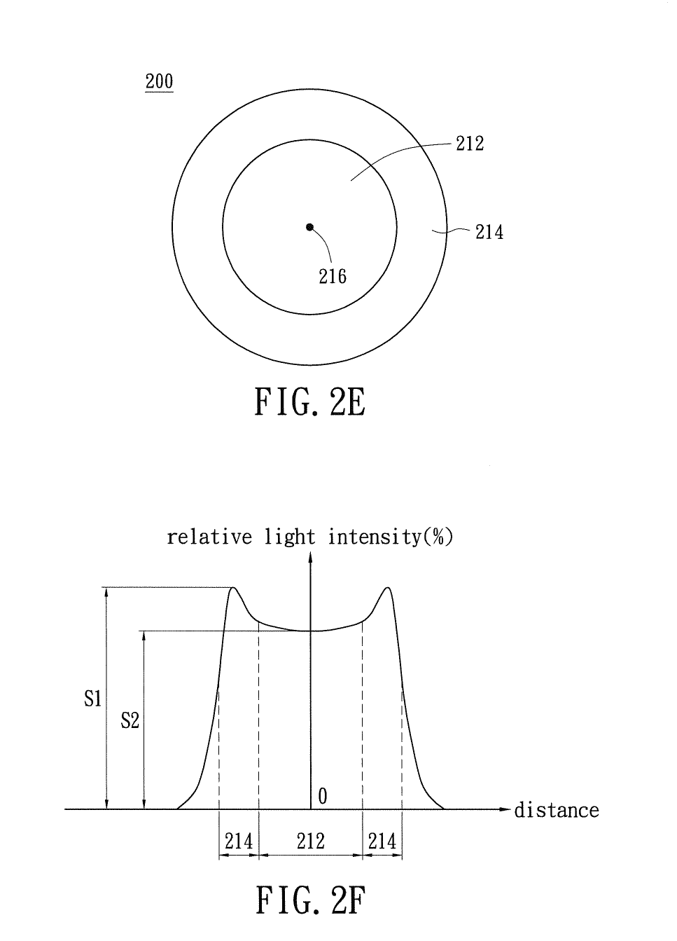

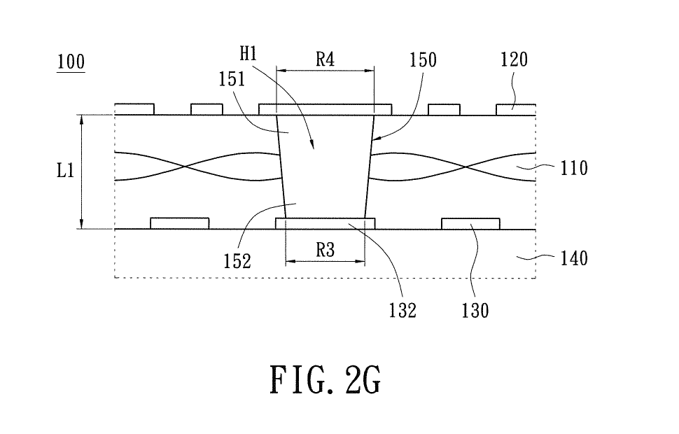

FIG. 2A˜FIG. 2G respectively show the flowchart diagram illustrating a laser drilling method for manufacturing a wiring board provided in accordance to an exemplary embodiment of the present disclosure. FIG. 2A˜FIG. 2F respectively illustrate the laser drilling method provided by the present disclosure and FIG. 2G shows a wiring board manufactured using the laser drilling method provided in the instant embodiment. Please refer to FIG. 2A, a wiring substrate 100′ is provided. The wiring substrate 100′ is a semi-product of a wiring board, for instance a semi-product of a multilayer wiring board. The wiring substrate 100′ has at least a wiring layer.

To put it concretely, the wiring substrate 100′ includes a metal layer 120′, an insulation layer 110′, and an inner substrate 102. The insulation layer 110′ is disposed between the metal layer 120′ and the inner substrate 102. The metal layer 120′ is disposed above the insulation layer 110′. The inner substrate 102 includes a wiring. layer 130 and an insulation layer 140. The wiring layer 110′ is in contact with the metal layer 120′, the wiring layer 130, and the insulation layer 140. The wiring layer 130 is sandwiched between the insulation layer 110′ and the insulation layer 140. The wiring layer 130 further includes at least a contact pad 132. So that the wiring substrate 100′ has at least a wiring layer (i.e., the wiring layer 130).

In addition to the wiring layer 130, the inner substrate 102 may further includes other wiring layers (not shown) and a plurality of conductors (not shown) electrically connecting the wiring layer 130 and other wiring layers. Specifically, the inner substrate 102 may have a plurality of through-holes (not shown), blind vias (not shown), and buried vias (not shown). The conductors can be respectively disposed in the through-holes, blind vias, and buried vias. The through-holes extend to the insulation layer 140 and at least a blind via is disposed in the insulation layer 140.

Nevertheless, it shall be noted that in the instant embodiment, through-holes, blind vias. and buried vias can be selectively arranged in the inner substrate 102. For instance, the inner substrate 102 may only have through-holes disposed therein and no blind vias or buried vias. Or, the inner substrate 102 may only have blind vias and buried vias and no through-holes. Thus, the instant embodiment does not limit actual via design (e.g., through-holes, blind vias, or buried vias) for arranging conductor therein in the inner substrate 102.

The metal layer 120′ may be metal foil such as copper foil or aluminum foil. Additionally, the meal layer 120′ may be a metal foil with reduction in thickness. In particular, the metal layer 120′ may be a metal foil after etching or polishing. Moreover, the insulation layer 110′ in the instant embodiment may be a cured prepreg. The insulation layer 110′ thus may include a polymeric material 112 and a fiberglass 114, wherein the fiberglass 114 is impregnated with polymeric material 112.

The polymeric material 112 may be selected from the group consisting of epoxy, modified epoxy, polyester, acrylic ester, fluoro-polymer, polyphenylene oxide, polymide, phenolicresin, polysulfone, silicone polymer, bismaleimide triazine modified epoxy, cyanate ester, polyethylene, polycarbonate, acrylonitrile-butadiene-styrene copolymer, polyethylene terephthalate, polybutylene terephthalate, liquid crystal polymers, polyamide 6, nylon, polyoxmethylene, polyphenlene sulfide, cyclic olefin copolymer, and combination of selected element thereof.

Even though the insulation layer 110′ in the instant embodiment is comprised of polymeric material 112 and fiberglass 114, however, in other embodiments, the insulation layer 110′ may only comprise of polymeric material 112 and does not comprise of fiberglass 114. Or, the insulation layer 110′ may be a ceramic layer and does not comprise of any polymeric material 112 and fiberglass 114. Accordingly, the insulation layer 110′ depicted in FIG. 2A is merely provided as an example and the present disclosure is not limited thereto.

Next, please refer to FIG. 2A and FIG. 2B, at least a portion of metal layer 120′ is removed to form at least an opening 122. The opening 122 partially exposes the insulation layer 110′ and is directly above the contact pad 132. There are many methods for removing the metal layer 120′ and the instant embodiment uses photolithography and etching techniques to remove a portion of the metal layer 120′. The etching may be dry etching or wet etching technique. Additionally, although FIG. 2B only depicts an opening 122, however in practice two or more openings 122 may be formed according to different layout design. Thus the opening 122 of FIG. 2B merely serves as an illustration and the present disclosure is not limited thereto.

Please refer to FIG. 2C and FIG. 2D, shining a laser beam 200 on the wiring substrate 100′ to remove at least a portion of the insulation layer 110′ and form an insulation layer 110 having at least a blind via H1. The blind via H1 partially exposes the contact pad 132. The laser beam 20 may be a light beam having wavelength ranging from infrared to ultraviolet. In particular, the wavelength of the laser beam 200 may range from 256 nm to 10200 nm. The laser beam 200 in the instant embodiment may be generated by a CO₂ laser generator so that the wavelength of the laser beam 200 may approximately be 8000 nm.

The laser beam 200 shines on the portion of the insulation layer 110′ being exposed by the opening 122 to remove the insulation layer 122 exposed by the opening 122. When the wavelength of the laser beam 200 is in the visible light region, e.g., the wavelength of the laser beam 200 being 248 nm, as the absorption rate of the metal layer 120′ to the laser beam 200 is relative low so the metal layer 120′ will not be easily removed by the laser beam 200. However, the insulation layer 110′ on the other hand has high absorption rate to the laser beam 200. Thus, when the laser beam 200 shines on the opening 122, the portion of the insulation layer 110′ exposed can be removed by the laser beam 200 to form the blind via H1.

It is worth to note that although in the instance embodiment, the process of forming the blind via H1 includes removing a portion of metal layer 120′ to form the opening 122 for partially exposing the insulation layer 110′, however selecting a laser beam 200 with proper wavelength may also remove a portion of metal layer 120′. For instance, laser beam 200 having the wavelength outside of ultraviolet (e.g., the wavelength of 248 nm) can also remove a portion of the metal layer 120′. In other embodiment, the laser beam 200 can directly shine on the metal layer 120′ without removing a portion of metal layer 120′. Alternatively, the steps described from FIG. 2A to FIG. 2B may be skipped and the metal layer 120′ of FIG. 2C may be replaced with the metal layer 120′ of FIG. 2A.

The laser beam 200 may be a pulsed laser beam and is a focused laser beam. The laser beam 200 has a focus section 210, wherein the focus section 210 is the section in the depth of focus (DOF) D1 of the laser beam 200. The length of focus section 210 as shown in FIG. 2C is equal to the DOF D1. Moreover, when the laser beam 200 shines on the wiring substrate 100′, the wiring substrate 100′ is placed in the focus section, and the beam waist 210w of the laser beam 200 and the focus 210f are located above the wiring substrate 100′.

Please refer to FIG. 2E and FIG. 2F, wherein FIG. 2E illustrates a cross section view of the laser beam 200 in the focus section 210 and FIG. 2F illustrates the light intensity distribution of laser beam 200 according to the cross section view of FIG. 2E. The horizontal axis in FIG. 2F represents the distance from an optical axis 216 and the zero points on the horizontal axis represent the position of the optical axis 216. The focus section 210 of the laser beam 200 contains a central region 212, the optical axis 216 located in the central region 22, and a peripheral region 214 surrounding the central region 212. The laser beam 200 may be generated by a beam shaper.

Different from the light intensity distribution of Gauss distribution and the top-hat distribution, the maximum light intensity S1 of the focus section 210 is neither in the optical axis 216 nor in the central region 212 but in the peripheral region 214. The light intensity of the focus section 210 further as shown in FIG. 2F is gradually increasing from the central region 212 toward the peripheral region 214. The ratio of a minimum light intensity S2 of the focus section to the maximum light intensity S1 thereof in the 210 central region 212 lies between 0.8 to 0.95.

Please refer again to FIG. 2C and FIG. 2D, since the maximum light intensity S1 appears in the peripheral region 214 of the focus section 210 (as shown in FIG. 2F), the attenuation of the light intensity in the edge region of the focus section 210 is relative low and the DOP D1 is relative long compare to the focused laser beam having the Gauss distribution or the top-hat distribution. The laser beam 200 thus can form a blind via H1 with high aspect ratio in the insulation layer 110′.

To put it concretely, the blind via H1 has a bottom diameter R1 and an opening diameter R2. In comparison to the blind via formed using the focused laser beam with the Gauss distribution or the top-hat distribution, the ratio between the bottom diameter R1 and the opening diameter R2 is relative large. The ratio in the instant embodiment may be larger than or equal to 0.75 but smaller than 1. That is, in comparison to the blind via in modern wiring board, the bottom diameter R1 is relatively closer to the opening diameter R2. A desmear process may be performed after the formation of blind via H1 to clean the surface of contact pad 132 exposed by the blind via H1.

Please refer to FIG. 2G, forming a conductor 150 in the blind via H1 and a wiring layer 120 on the insulation layer 110. The conductor 150 may be formed by plating through-hole and the wiring layer 120 may be formed by using plating, photolithography and etching techniques. The wiring layer 120 can be formed by performing semi-additive or subtractive process to the metal layer 120′. Such that the formation steps of the wiring layer 120 may include etching the metal layer 120′. Additionally, when the wiring layer 120 is formed using semi-additive process, the etching technique used to etch the metal layer 120′ may be micro-etching.

A wiring board 100 is substantially manufactured after the formation of the conductor 150 and the wiring layer 120. The wiring board 100 may be a multilayer wiring board. The wiring board 100 includes wiring layers 120, 130, the insulation layer 110 disposed between the wiring layers 120, 130, and the conductor 150 electrically connecting the wiring layers 120, 130. The insulation layer 110 may be in contact with the wiring layers 120 and 130. The number of the conductor 150 disposed may equal to the number of the blind via H1. In particular, when there are multiple blind vias H1, there can also be multiple conductors 150 formed therein. Accordingly, the number of conductors included in the wiring board 100 of FIG. 2G merely serves as an example and the present disclosure is not limited thereto.

The conductor 150 has a first end 151 and a second end 152 opposite to the first end 151. A width R4 of the first end 151 may be larger than a width R3 of the second end 152. The conductor 150 basically fills the entire blind via H1. So that the width R3 is substantially equal to bottom diameter R1 of the blind via H1 (shown in FIG. 2D) and the width R4 is substantially equal to the opening diameter R2 of blind via H1 (shown in FIG. 2D).

Accordingly, the ratio of the width R3 of the second end 152 to the width R4 of the first end 151 may be larger than or equal to 0.75 but smaller than 1. Such that the width R4 of the conductor 150 is relatively closer to the width R3 in comparison to the modern wiring board. The aspect ratio of the conductor 150 may range from 0.8 to 5 wherein the aspect ratio is the ratio between a length L1 of the conductor 150 and the width R3 of the second end 152.

In summary, different from the existing focused laser beam having either the Gauss distribution or the top-hat distribution, the present disclosure uses the laser beam having the maximum light intensity in the peripheral region to manufacture a blind via on a wiring board so that the attenuation of the light intensity of the laser beam in the edge region (e.g., located in the focus section) may be reduced thereby increase the via diameter ratio of the blind via e.g., 0.75. Such that the contact area between the conductor formed thereafter in the blind via and the contact pad disposed under the blind via can be increased to increase the bonding strength between the conductor and the contact pad thereby improve the reliability of the wiring board.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A laser drilling method of a wiring board, comprising:
shining a laser beam on a wiring substrate comprising an insulating layer to remove a portion of the insulation layer, wherein the wiring substrate is placed in a focus section of the laser beam, the focus section having a central region, an optical axis located in the central region, and a peripheral region surrounding the central region, a maximum light intensity of the focus section appeared in the peripheral region.

2. The laser drilling method according to claim 1, wherein the light intensity of the focus section is gradually increasing from the central region toward the peripheral region.

3. The laser drilling method according to claim 1, wherein the ratio of a minimum light intensity of the focus section to the maximum light intensity thereof in the central region lies between 0.8 to 0.95.

4. The laser drilling method according to claim 1, wherein when the laser beam shines on the wiring substrate, a beam waist of the laser beam is located above the wiring substrate.

5. The laser drilling method according to claim 1, wherein the laser beam is a pulsed laser beam.

6. The laser drilling method according to claim 1, wherein the wavelength of the laser beam ranges from 256 nm to 10200 nm.

7. The laser drilling method according to claim 1, wherein the wiring substrate further comprises a metal layer, the metal layer is disposed on the insulation layer, removing a portion of the metal layer before shining the laser beam on the wiring substrate to form an opening exposing the insulation layer, wherein the laser beam shines on the portion of the insulation layer exposed by the opening.

8. A wiring board, comprising:
an insulation layer:
two wiring layers, the insulation layer disposed between the wiring layers; and
at least a conductor, disposed in the insulation layer, and electrically connected to the wiring layer, wherein the conductor has a first end and a second end opposite to the first end, the width of the first end being larger than the width of the second end, and the ratio of the width of the second end to the width of the first end being larger than or equal to 0.75.

9. The wiring board according to claim 8, wherein the ratio of the width of the second end to the width of the first end is smaller than 1.

10. The wiring board according to claim 8, wherein the aspect ratio of at least one conductor lies between 0.8 to 5.

11. The wiring board according to claim 8, wherein the insulation layer is in contact with the wiring layer.

12. The wiring board according to claim 8, wherein the insulation layer comprises a polymeric material, the polymeric material being selected from the group consisting of epoxy, modified epoxy, polyester, acrylic ester, fluoro-polymer, polyphenylene oxide, polymide, phenolicresin, polysulfone, silicone polymer, bismaleimide triazine modified epoxy, cyanate ester, polyethylene, polycarbonate, acrylonitrile-butadiene-styrene copolymer, polyethylene terephthalate, polybutylene terephthalate, liquid crystal polymers, polyamide 6, nylon, polyoxmethylene, polyphenlene sulfide, cyclic olefin copolymer, and combination of selected element thereof.

13. The wiring board according to claim 12, wherein the insulation layer further comprises a fiberglass, and the fiberglass is impregnated with polymeric material.

14. The wiring board according to claim 8, wherein the insulation layer is a ceramic layer.
